(19) United States
(12) Patent Application Publication
(10) Pub. No.: US 2007/0040592 A1
(43) Pub. Date: Feb. 22, 2007

(54) Semiconductor integrated circuit device

(75) Inventor: Nobuhiro Ooki, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 11/498,047

(22) Filed: Aug. 3, 2006

(30) Foreign Application Priority Data
Aug. 19, 2005 (JP) 2005-238866

(51) Int. Cl. H03B 19/00

(52) U.S. Cl. 327/116

(57) ABSTRACT

To provide a circuit that has a high multiplication ratio and low jitter and that operates stably. A multiplication circuit 10 comprises a selector circuit 15 for selecting an input clock signal CLK or a clock signal obtained by multiplying the input clock signal CLK by m and outputting it. A PLL circuit 20 comprises a phase/frequency detector circuit 21 for comparing the phases of the clock signal outputted from the selector circuit 15 and a feedback clock signal, a charge pump circuit 22 for receiving a phase difference signal outputted from the phase/frequency detector circuit 21, a low-pass filter 23 for extracting and outputting the low-frequency component of a signal outputted from the charge pump circuit 22, a voltage-controlled oscillator 24 that oscillates at a frequency corresponding to the output level of the low-pass filter 23, and a frequency divider 25 for receiving an output clock of the voltage-controlled oscillator 24, frequency-dividing it by n, and outputting the result as the feedback clock signal.

### FIELD OF THE INVENTION

The present invention relates to a semiconductor integrated circuit device and particularly to a semiconductor integrated circuit device including a multiplication Phase Locked Loop PLL circuit.

### BACKGROUND OF THE INVENTION

A multiplication PLL circuit is widely used to generate a high-frequency clock from a reference clock with a low frequency. Such a multiplication PLL circuit is also used to generate a synchronous clock for data transmission between devices. In recent years, data transfer speed between devices has increased and transmission at a high data rate has been realized. In such high data rate transmission, parallel transmission has reached its transfer speed limit because it becomes more difficult to obtain the skew between parallel signals as the transmission speed increases. Therefore, it has become more common to use serial transmission for high-speed transmission.

In such a multiplication PLL circuit, a circuit structure in which the frequency multiplication ratio is selectable according to the needs is known. For instance, a PLL frequency multiplying circuit whose frequency multiplication ratio is selectable and that realizes a high multiplication ratio is disclosed in Patent Document 1.

FIG. 4 is a block diagram illustrating the structure of the PLL frequency multiplying circuit described in Patent Document 1. In FIG. 4, the PLL frequency multiplying circuit has a phase/frequency detector circuit 110 compare the phases of a reference clock signal and a feedback clock signal and supplies the phase difference to a voltage-controlled oscillator (VCO) 140 via a charge pump circuit 120 and a low-pass filter 130. The output frequency of the voltage-controlled oscillator 140 is controlled according to an output signal of the low-pass filter 130. Further, the PLL frequency multiplying circuit comprises a counter 151 that receives the output clock of the voltage-controlled oscillator 140 and a first multiplexer circuit 152 that receives a plurality of clock signals taken out of each stage of the outputs of the counter 151 and that supplies a selected signal to the phase/frequency detector circuit 110 as the feedback clock signal. It also comprises a circuit 160 that generates a multiplied clock having a higher frequency than the VCO output frequency using the signal from the voltage-controlled oscillator 140, a second multiplexer 170 that receives the VCO output clock and the multiplied clock, and an N-ary counter 180 that receives an output clock signal selected by the second multiplexer. With the PLL frequency multiplying circuit structured as described above, the frequency multiplication ratio is selectable and higher multiplication ratios than those of conventional PLL circuits can be achieved, solving the problem that the maximum operating frequency of a feedback counter becomes restricted when the multiplication ratio increases.

[Patent Document 1]

Japanese Patent Kokai Publication No. JP-P2001-16077A (FIG. 1)

### SUMMARY OF THE DISCLOSURE

In the PLL frequency multiplying circuit shown in FIG. 4, the counter 151 is provided within the feedback loop and the signal selected by the first multiplexer circuit 152, which receives a plurality of clock signals taken out of each stage of the outputs of the counter 151, is supplied to the phase/frequency detector circuit 110 as the feedback clock signal. In the circuit structured as above, every time the first multiplexer circuit 152 selects a clock signal in order to change the multiplication ratio, the characteristics of the PLL circuit change. For instance, the time it takes for the PLL circuit to be locked (i.e., the oscillation frequency is stabilized) after being turned on or reset changes. Therefore, every time the multiplication ratio is changed, the number of clocks needed to be counted after being turned on or reset, i.e., the time a circuit that uses the clock signal outputted by the PLL circuit needs to wait until normal operation starts must be changed as well.

Meanwhile, the multiplied clock generated by the circuit 160 is synthesized from signals taken out of each stage of an odd number of inverter circuits that constitute the voltage-controlled oscillator 140 or each stage of a ring oscillator where a plurality of differential amplifier circuits are ring-connected. In the ring oscillator structured as above, since active elements connected in multiple stages operate, jitter occurs comparatively often and becomes notable especially when the frequency division ratio is large.

Accordingly there is much to be desired in the art.

A semiconductor integrated circuit device relating to a first aspect of the present invention comprises a multiplication circuit that multiplies and outputs an input clock signal and that is structured so that the multiplication ratio is selectable; and a Phase Locked Loop PLL circuit for multiplying an output signal of the multiplication circuit by n (where n is a natural number) and outputting it as an output clock signal.

According to a second aspect, the multiplication circuit comprises a selector circuit that selects a ratio out of a plurality of the multiplication ratios not less than two.

According to a third aspect, the selector circuit selects whether to output the input clock signal as it is or to multiply the input clock signal by m where m is an integer not less than 2, and output the result.

According to a fourth aspect, a voltage-controlled oscillator is included in the PLL circuit and is comprised of an inductor and a voltage-variable capacitance element.

According to a fifth aspect, the semiconductor integrated circuit device further comprises an input terminal; a serial-parallel conversion circuit that converts a first serial signal supplied through the input terminal into a first parallel signal in synchronization with the output clock signal and outputting it to an internal circuit; an output terminal; and a parallel-serial conversion circuit that converts a second parallel signal generated by the internal circuit into a second serial signal in synchronization with the output clock signal and outputting it to the output terminal.

According to a sixth aspect, the semiconductor integrated circuit device further comprises a test input terminal connected to the selector circuit, wherein the multiplication circuit multiplies the input clock signal by m where m is an integer not less than 2 and outputs the result when the test input terminal is set in a test mode.

The meritorious effects of the present invention are summarized as follows.

According to the present invention, a circuit that has low jitter and a high multiplication ratio and that operates stably can be realized.

### BRIEF DESCRIPTIONS OF THE DRAWINGS

FIG. 1 is a block diagram illustrating the structure of a multiplication circuit and PLL circuit relating to an embodiment of the present invention.

FIGS. 2A and 2B are circuit diagrams of a clock multiplier.

FIG. 3 is a block diagram illustrating the structure of the semiconductor integrated circuit device relating to the embodiment of the present invention.

FIG. 4 is a block diagram illustrating the structure of a conventional PLL frequency multiplying circuit.

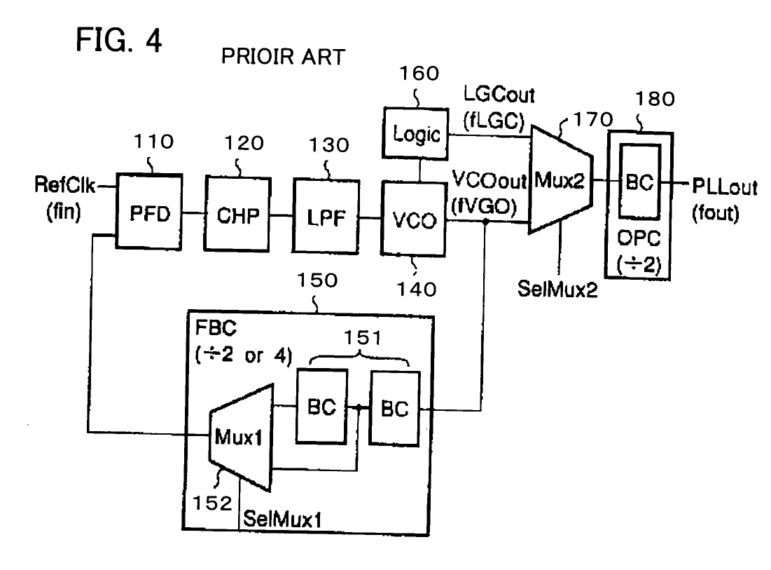

### PREFERRED EMBODIMENTS OF THE INVENTION

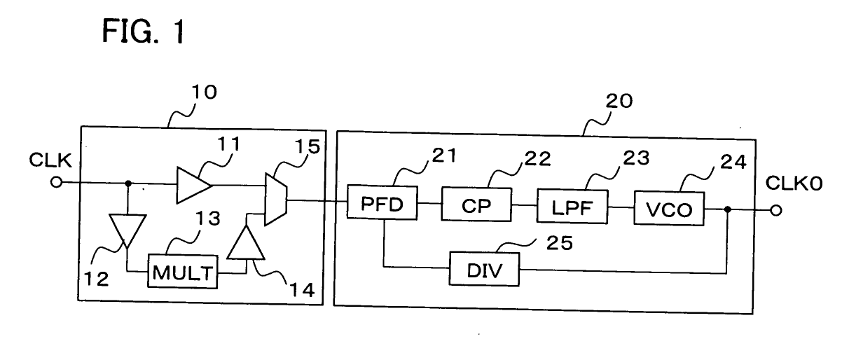

FIG. 1 is a block diagram illustrating the structure of a multiplication circuit and PLL circuit relating to an embodiment of the present invention. In FIG. 1, the multiplication circuit 10 comprises buffers 11 and 12 that buffer an input clock signal CLK, a clock multiplier (MULT) 13 that multiplies a signal outputted from the buffer 12 by m (where m is an integer not less than 2), a buffer 14 that buffers a signal outputted from the clock multiplier 13, and a selector circuit 15 that selects one of signals outputted from the buffer 11 or from the buffer 14. Further, the buffers 11, 12, and 14 may have the function of waveform shaping and they may be inserted as necessary.

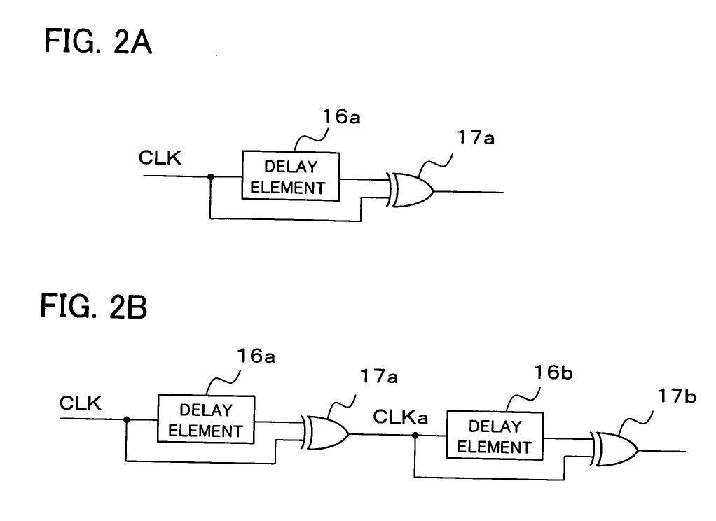

The concrete structure of the clock multiplier 13 is shown in FIGS. 2A and 2B. The clock multiplier shown in FIG. 2A comprises a delay element 16a having a delay time equal to a quarter of a cycle of the clock signal CLK and an exclusive-OR circuit 17a. For instance, the delay element 16a is constituted by buffers (gates) connected in multiple stages. The exclusive-OR circuit 17a outputs a clock signal having the frequency double of the frequency of the clock signal CLK by calculating the exclusive-OR (EXOR) of the clock signal CLK and the clock signal CLK delayed by the delay element 16a.

Further, the clock multiplier shown in FIG. 2B further comprises a delay element 16b having a delay time equal to one-eighth of a cycle of the clock signal CLK and an exclusive-OR circuit 17b. By calculating the exclusive-OR (EXOR) of a clock signal CLKa outputted from a clock multiplier the same as the one shown in FIG. 2A and the clock signal CLKa delayed by the delay element 16b, the exclusive-OR circuit 17b outputs a clock signal having the frequency double of the frequency of the clock signal CLKa, i.e., the frequency four times as much as that of the clock signal CLK.

When the clock multiplier 13 is the clock multiplier shown in FIGS. 2A or 2B, the multiplication circuit 10 has the selector circuit 15 select the clock signal CLK, the clock signal having the frequency double of that of the clock signal CLK, or the clock signal having the frequency four times as much as that of the clock signal CLK, and outputs the selected clock signal.

Meanwhile, the PLL circuit 20 comprises a phase/frequency detector circuit (PFD) 21 for comparing the phases of the clock signal outputted from the multiplication circuit 10 and a feedback clock signal, a charge pump circuit (CP) 22 for receiving a phase difference signal outputted from the phase/frequency detector circuit 21, a low-pass filter (LPF) 23 for extracting and outputting the low-frequency component of a signal outputted from the charge pump circuit 22, a voltage-controlled oscillator (VCO) 24 that oscillates at a frequency corresponding to the output level of the low-pass filter 23, and a frequency divider (DIV) 25 for receiving and frequency-dividing an output clock of the voltage-controlled oscillator 24 by n (where n is a natural number), and an output signal of the frequency divider 25 is supplied to the phase/frequency detector circuit 21 as the feedback clock signal.

Here, it is preferable that the voltage-controlled oscillator 24 include a voltage-variable capacitance element (e.g., varactor diode) whose capacitance varies greatly 5 according to the voltage applied to the junction and an inductor. A voltage-controlled oscillator comprised of such elements has a stable oscillation frequency and low jitter, unlike a ring oscillator comprised of active elements connected in multiple stages.

Further, the frequency division ratio n of the frequency divider 25 is fixed in the PLL circuit 20. As a result, the circuit conditions within the loop become fixed, making the characteristics of the PLL circuit very stable.

In the circuit structured as described above, the input clock signal CLK selected by the selector circuit 15 or a clock signal obtained by multiplying the input clock signal CLK by m is supplied to the PLL circuit 20 from the multiplication circuit 10. Therefore, a signal having a frequency n times or m×n times that of the input clock signal CLK is outputted from the PLL circuit 20. Since the PLL circuit is structured as described, an output signal outputted from the PLL circuit 20 is stable and has low jitter. In other words, a circuit that operates stably and has low jitter and a high multiplication ratio is realized by the multiplication circuit 10 and the PLL circuit 20. Hereinafter, a concrete example of a semiconductor integrated circuit device to which the multiplication circuit 10 and the PLL circuit 20 are applied is described with reference to an embodiment.

### EMBODIMENT 1

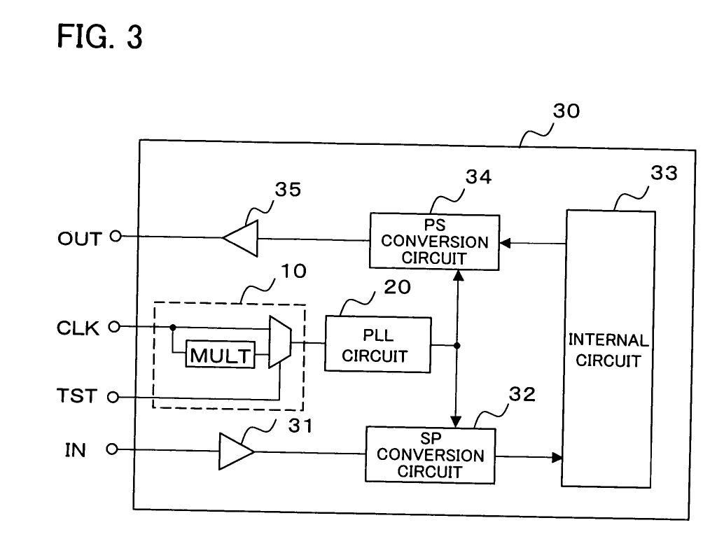

FIG. 3 is a block diagram illustrating the structure of the semiconductor integrated circuit device relating to an embodiment of the present invention. In FIG. 3, the semiconductor integrated circuit device 30 is used for serial communication between devices. The semiconductor integrated circuit device 30 comprises the multiplication circuit 10 and the PLL circuit 20 shown in FIG. 1, buffer circuits 31 and 35, a serial-parallel (SP) conversion circuit 32, an internal circuit 33, and a parallel-serial (PS) conversion circuit 34.

The clock signal CLK is supplied to the PLL circuit 20, with or without being multiplied by the multiplication circuit 10. The clock signal outputted from the PLL circuit 20 is supplied to the serial-parallel conversion circuit 32 and to the parallel-serial conversion circuit 34. A serial data signal IN is supplied to the serial-parallel conversion circuit 32 via the buffer circuit 31. Based on the clock signal outputted from the PLL circuit 20, the serial-parallel conversion circuit 32 receives the serial data signal IN, converts it into a parallel data signal, and outputs it to the internal circuit 33.

Meanwhile, the parallel-serial conversion circuit 34 converts the parallel data signal supplied from the internal circuit 33 to the parallel-serial conversion circuit 34 into a serial data signal based on the clock signal outputted from the PLL circuit 20 and outputs it as a serial data signal OUT via the buffer circuit 35.

In the semiconductor integrated circuit device as structured as above, the multiplication circuit 10 selects the clock signal CLK or a clock signal obtained by multiplying the clock signal CLK according to the signal level of a test signal TST, and outputs it to the PLL circuit 20. For instance, a clock signal obtained by multiplying the clock signal CLK is outputted to the PLL circuit 20 when the semiconductor integrated circuit device shown in FIG. 3 operates in a test mode, and the clock signal CLK is outputted to the PLL circuit 20 without being multiplied when the semiconductor integrated circuit device operates in its normal operation mode. By having the test signal TST set the device in the test mode when testing the PLL 20 and its surrounding parts, the device can operate with a clock signal CLK having a frequency lower than the one needed for the normal operation. By doing this, it becomes possible to use a less expensive tester operating with a clock signal CLK having a lower frequency when testing the semiconductor integrated circuit device 30, and the test conditions can be mitigated because the frequency of the clock signal CLK is low.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A semiconductor integrated circuit device comprising:
a multiplication circuit that multiplies and outputs an input clock signal and that is structured so that the multiplication ratio is selectable; and
a Phase Locked Loop PLL circuit that multiplies an output signal of said multiplication circuit by n where n is a natural number, and outputs it as an output clock signal.

2. The semiconductor integrated circuit device as defined in claim 1 wherein said multiplication circuit comprises a selector circuit that selects a ratio out of a plurality of said multiplication ratios not less than two.

3. The semiconductor integrated circuit device as defined in claim 2 wherein said selector circuit selects whether to output said input clock signal as it is or to multiply said input clock signal by m where m is an integer not less than 2, and output the result.

4. The semiconductor integrated circuit device as defined in claim 1 wherein a voltage-controlled oscillator included in said PLL circuit is comprised of an inductor and a voltage-variable capacitance element.

5. The semiconductor integrated circuit device as defined in claim 3 further comprising:
an input terminal;
a serial-parallel conversion circuit that converts a first serial signal supplied through said input terminal into a first parallel signal in synchronization with said output clock signal and outputting it to an internal circuit;
an output terminal; and
a parallel-serial conversion circuit that converts a second parallel signal generated by said internal circuit into a second serial signal in synchronization with said output clock signal and outputting it to said output terminal.

6. The semiconductor integrated circuit device as defined in claim 3 further comprising a test input terminal connected to said selector circuit, wherein
said multiplication circuit multiplies said input clock signal by m where m is an integer not less than 2 and outputs the result when said test input terminal is set in a test mode.

7. The semiconductor integrated circuit device as defined in claim 5 further comprising a test input terminal connected to said selector circuit, wherein
said multiplication circuit multiplies said input clock signal by m where m is an integer not less than 2 and outputs the result when said test input terminal is set in a test mode.
